(19) United States
(12) Patent Application Publication
(10) Pub. No.: US 2013/0335934 A1
(43) Pub. Date: Dec. 19, 2013

(54) MOUNTING DEVICE FOR CONNECTOR

(71) Applicants: JUN-HUI WANG, Shenzhen City (CN); AI-LING HE, Shenzhen City (CN)

(72) Inventors: JUN-HUI WANG, Shenzhen City (CN); AI-LING HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/554,118

(22) Filed: Jul. 20, 2012

(30) Foreign Application Priority Data
Jun. 19, 2012 (CN) 2012102027423

(51) Int. Cl. H05K 5/02

(52) U.S. Cl. 361/759

(57) ABSTRACT

A device for mounting a connector includes a base board forming two rods, a motherboard supporting the connector, and a fixing member including a main body and two legs. The rods extend through the motherboard, positioned at opposite sides of the connector. Each rod includes a resilient member, and a ball mounted to a distal end of the resilient member and partly extending out of the rod. Each leg includes a fixing piece defining a through hole fitting about one of the rods. The balls partly extend out of the rods to block tops of the corresponding fixing pieces. The connector is sandwiched between the fixing member and the motherboard.

### BACKGROUND

1. Technical Field

The present disclosure relates to mounting devices, and especially to a device for mounting a quad small form-factor pluggable (QSFP) connector.

2. Description of Related Art

QSFP connectors are elongated, as a result, when a QSFP connector is mounted to a motherboard, a mounting device is needed to fix a rear end of the QSFP connector, for preventing the rear end of the QSFP connector from tilting up. However, the mounting device may be mounted to the motherboard by screws, which makes it difficult and time-consuming to replace or remove the QSFP connector.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device, together with two quad small form-factor pluggable (QSFP) connectors.

FIG. 2 is an assembled, isometric view of the mounting device and the QSFP connectors of FIG. 1.

FIG. 3 is a cross-sectional view of FIG. 2, taken along the line of III-III.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

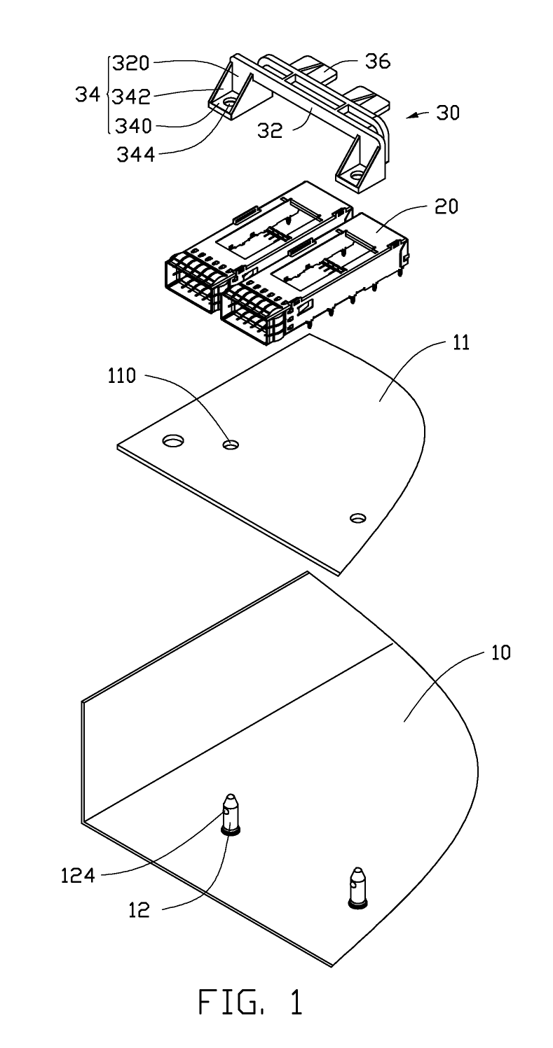

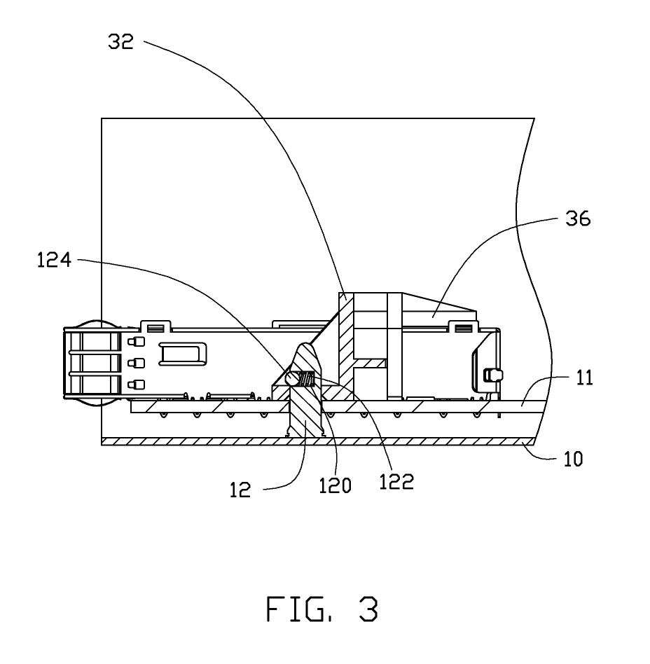

Referring to FIGS. 1 and 3, an exemplary embodiment of a mounting device is provided for mounting two elongated quad small form-factor pluggable (QSFP) connectors 20. The mounting device includes a base board 10, a motherboard 11 mounted on the base board 10, and a fixing member 30.

The motherboard 11 defines two first through holes 110. The QSFP connectors 20 are mounted on the motherboard 11 and are positioned between the first through holes 110. Two rods 12 each having a tapered top end protruding from the base board 10 and extend through the first through holes 110 of the motherboard 11, respectively. The rods 12 are positioned at opposite sides of the QSFP connectors 20.

Each rod 12 defines a receiving hole 120, adjacent to a top end of the rod 12. The receiving hole 120 extends through a circumference of the rod 12. A resilient member 122 is received in the receiving hole 120, with a first end of the resilient member 122 abutting a blind end of the receiving hole 120. A ball 124 is mounted to a second end of the resilient member 122, opposite to the first end. The ball 124 partly extends out of the circumference of the rod 12. In this embodiment, the resilient member 122 is a spring.

The fixing member 30 includes a bar-shaped main body 32, two legs 34 extending down from opposite ends of the main body 32, and two plates 36 extending rearward from a rear side of the main body 32. Each leg 34 includes an extension piece 320, perpendicularly extending down from a corresponding end of the main body 32; a fixing piece 340, perpendicularly extending forward from a bottom end of the extension piece 320 opposite to the main body 32; and two connecting pieces 342, connected between opposite sides of the extension piece 320 and the fixing piece 340. The fixing piece 340 defines a second through hole 344. The second through hole 344 includes a cylindrical hole and a tapered hole below and communicating with the cylindrical hole.

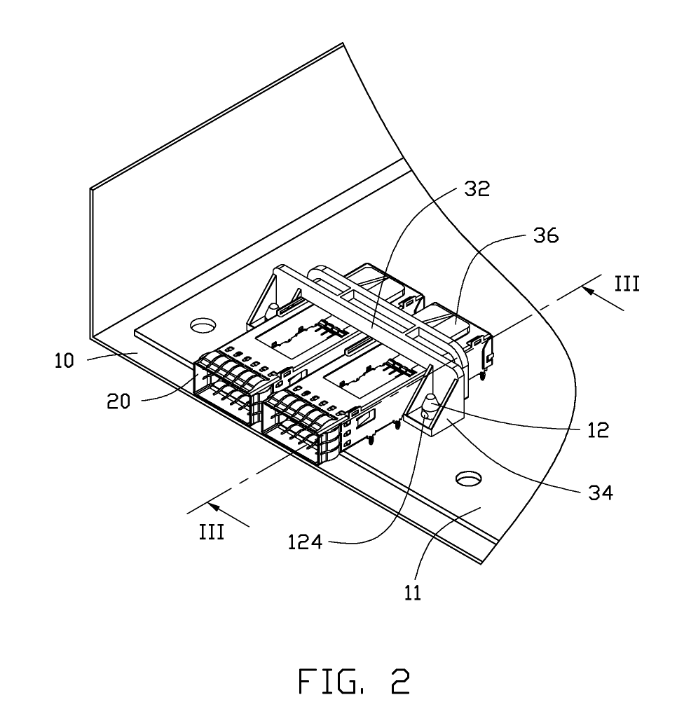

Referring to FIGS. 2 and 3, in fixing the QSFP connectors 20, the second through holes 344 are fitted about the corresponding rods 12. An inner surface of the cylindrical hole of each second through hole 344 presses the ball 124 into the receiving hole 120 to deform the resilient member 122 of the corresponding rod 12, until the ball 124 is received in the receiving hole 120 completely. The second through holes 344 pass by the balls 124 and the fixing pieces 340 contact the motherboard 11. The resilient members 122 are then restored and bias the balls 124 to partly extend out of the rods 12 to block a top of the corresponding fixing piece 340, to fix the fixing member 30 to the motherboard 11. Therefore, the QSFP connectors 20 are sandwiched between the fixing member 30 and the motherboard 11. Each plate 36 abuts a top of a rear end of a corresponding one of the QSFP connectors 20.

In uninstalling one of the QSFP connectors 20, the balls 124 are pressed to be completely received in the corresponding receiving holes 120. The fixing member 30 is then readily taken up and disengages the rods 12 from the corresponding second through holes 344.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for a connector, comprising:
a base board comprising two rods each defining a receiving hole having a blind end, a resilient member received in the receiving hole and having a first end abutting the blind end of the receiving hole, and a ball connects to a second end of the resilient member opposite to the first end and partly extends out of the circumference of the rod;
a motherboard, mounted on the base board, defining two first through holes fitting about the rods; and
a fixing member comprising a main body and two legs extending down from opposite ends of the main body, each leg comprising a fixing piece defining a second through hole;
wherein the connector is mounted on the motherboard, the rods are positioned at opposite sides of the connector, the second through holes of the fixing member are fitted about the rods, the balls block tops of the corresponding fixing pieces.

2. The mounting device of claim 1, wherein each leg further comprises an extension piece perpendicularly extending down from the main body, and the fixing piece of each leg perpendicularly extends out from a bottom end of the corresponding extension piece opposite to the main body.

3. The mounting device of claim 2, wherein each leg further comprise two connecting pieces connected between opposite sides of the extension piece and the fixing piece of the leg.

4. The mounting device of claim 2, wherein a plate extends out from the main body abuts a top of the connector.

5. The mounting device of claim 1, wherein the resilient member is a spring.
